(19) United States
(12) Patent Application Publication
(10) Pub. No.: US 2007/0145508 A1
(43) Pub. Date: Jun. 28, 2007

(54) CMOS Image Sensor and Method for Manufacturing the Same

(76) Inventor: Woo Seok Hyun, Seo-gu (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/611,309

(22) Filed: Dec. 15, 2006

(30) Foreign Application Priority Data
Dec. 28, 2005 (KR) 10-2005-0132366

(51) Int. Cl. H01L 31/06

(52) U.S. Cl. 257/462

(57) ABSTRACT

A CMOS image sensor and a fabrication method thereof are provided. The CMOS image sensor includes a semiconductor substrate having an active area and an isolation area; a photodiode area and a transistor area defined on the active area; a plurality of semiconductor patterns formed on the photodiode area; a transistor formed on the transistor area; a first conductive type first diffusion region formed on the photodiode area; a first conductive type second diffusion region formed on the transistor area; and a second conductive type third diffusion region formed on the first diffusion region.

### RELATED APPLICATION(S)

This application claims priority under 35 U.S.C. § 119(e) of Korean Patent Application No. 10-2005-0132366 filed Dec. 28, 2005, which is incorporated herein by reference in its entirety

### FIELD OF THE INVENTION

The present invention relates to a complementary metal oxide semiconductor (CMOS) image sensor and a method for manufacturing the same.

### BACKGROUND OF THE INVENTION

In general, an image sensor is a semiconductor device for converting optical images into electric signals, and is mainly classified as a charge coupled device (CCD) or a CMOS image sensor.

The CCD has a plurality of photodiodes (PDs), which are arranged in the form of a matrix in order to convert optical signals into electric signals. The CCD includes a plurality of vertical charge coupled devices (VCCDs) provided between the photodiodes and are vertically arranged in the matrix so as to transmit electrical charges in the vertical direction when the electrical charges are generated from each photodiode. The CCD also includes a plurality of horizontal charge coupled devices (HCCDs) for transmitting the electrical charges of the VCCDs in the horizontal direction, and a sense amplifier for outputting electric signals by sensing the electrical charges being transmitted from the HCCDs.

However, the CCD has various disadvantages, such as a complicated drive mode and high power consumption. Also, the CCD requires multi-step photo processes, so the manufacturing process for the CCD is complicated.

In addition, since it is difficult to integrate a controller, a signal processor, and an analog/digital converter (A/D converter) onto a single chip of the CCD, the CCD is not suitable for compact-size products.

Recently, the CMOS image sensor has been spotlighted as a next-generation image sensor capable of solving the problem of the CCD.

The CMOS image sensor is a device employing a switching mode to sequentially detect an output of each unit pixel by means of MOS transistors, using peripheral devices, such as a controller and a signal processor. The MOS transistors are formed corresponding to each unit pixel.

That is, the CMOS image sensor includes a photodiode and a MOS transistor in each unit pixel, and sequentially detects the electric signals of each unit pixel in a switching mode to realize images.

Since the CMOS image sensor makes use of CMOS technology, the CMOS image sensor has advantages such as low power consumption and a simple manufacturing process with a relatively smaller number of photo processing steps.

In addition, the CMOS image sensor allows the product to have a compact size, because the controller, the signal processor, and the A/D converter can be integrated onto a single chip.

Therefore, CMOS image sensors have been extensively used in various applications, such as digital still cameras and digital video cameras.

CMOS image sensors are classified as 3T-type, 4T-type and 5T-type CMOS image sensors according to the number of transistors formed in a unit pixel. The 3T-type CMOS image sensor includes one photodiode and three transistors, and the 4T-type CMOS image sensor includes one photodiode and four transistors.

FIG. 1 is an equivalent circuit diagram illustrating a 4T-type CMOS image sensor according to a related art, and FIG. 2 is a layout view showing the 4T-type CMOS image sensor according to the related art.

As shown in FIG. 1, a unit pixel 100 of the CMOS image sensor includes a photodiode 10, which is an optoelectronic device, and four transistors.

Here, the four transistors include a transfer transistor 20, a reset transistor 30, a drive transistor 40, and a select transistor 50. In addition, a load transistor 60 is electrically connected to an output terminal OUT of each unit pixel 100.

Reference characters FD, Tx, Rx, Dx, and Sx represent a floating diffusion area, a gate voltage of the transfer transistor 20, a gate voltage of a reset transistor 30, a gate voltage of a drive transistor 40, and a gate voltage of a select transistor 50, respectively.

As shown in FIG. 2, the unit pixel of the CMOS image sensor has an active area defined thereon and where an isolation layer is formed on a predetermined area of the unit pixel except for the active area. The photodiode PD is formed on a wider region of the active area, and gate electrodes 23, 33, 43 and 53 of the four transistors are formed overlapping the remaining regions of the active area.

That is, the first gate electrode 23 corresponds to the transfer transistor 20, the second gate electrode 33 corresponds to the reset transistor 30, the third gate electrode 43 corresponds to the drive transistor 40, and the fourth gate electrode 53 corresponds to the select transistor 50.

Dopants are implanted into the active area of each transistor except for below lower portions of the gate electrodes 23, 33, 43 and 53, so that source/drain (S/D) areas of the transistors are formed.

FIGS. 3A to 3E are sectional views taken along line I-I′ of FIG. 2 to illustrate a procedure for fabricating a CMOS image sensor according to the related art.

Referring to FIG. 3A, an epitaxial process is performed relative to a high-density P⁺⁺ semiconductor substrate 61, thereby forming a low-density P⁻ epitaxial layer 62.

Then, after defining an active area and an isolation area on the semiconductor substrate 61, an isolation layer 63 is formed on the isolation area through an STI (shallow trench isolation) process.

Although not shown in the figures, the process for forming the isolation layer 63 is as follows:

First, a pad oxide layer, a pad nitride layer and a TEOS (tetra ethyl ortho silicate) oxide layer are sequentially formed on a semiconductor substrate. Then, a photoresist film is formed on the TEOS oxide layer.

After that, the photoresist film is subject to an exposure and development process using a mask that defines an active area and an isolation area, thereby patterning the photoresist film. At this time, the photoresist film formed on the isolation area is removed.

Then, the pad oxide layer, the pad nitride layer and the TEOS oxide layer on the isolation area are selectively removed using the patterned photoresist film as a mask.

Next, the isolation area of the semiconductor substrate is etched to a predetermined depth using the patterned pad oxide layer, pad nitride layer and TEOS oxide layer as an etch mask, thereby forming a trench. After that, the photoresist film is completely removed.

Then, the trench is filled with an insulating material, thereby forming the isolation layer 63 in the trench. After that, the pad oxide layer, the pad nitride layer and the TEOS oxide layer are removed.

Referring again to FIG. 3A, a gate insulating layer 64 and a conductive layer (for example, a high-density multi-crystalline silicon layer) are sequentially deposited on the entire surface of the epitaxial layer 62 formed with the isolation layer 63. Then, the conductive layer and the gate insulating layer 64 are selectively removed to form a gate electrode 65.

After that, referring to FIG. 3B, a first photoresist film 66 is coated on the entire surface of the semiconductor substrate 61. Then, the first photoresist film 66 is patterned through an exposure and development process in such a manner that blue, green and red photodiode areas can be exposed.

Next, low-density n type dopants are implanted onto the epitaxial layer 62 using the patterned first photoresist film 66 as a mask, to form a low-density n⁻ type diffusion area 67 for the blue, green and red photodiode areas.

Then, referring to FIG. 3C, the first photoresist film 66 is completely removed, and an insulating layer is deposited on the entire surface of the semiconductor substrate 61. Then, an etch-back process is performed to form an insulating layer sidewall 68 at both sides of the gate electrode 65.

Next, after coating a second photoresist film 69 on the entire surface of the semiconductor substrate 61, the second photoresist film 69 is patterned by exposure and development processes to cover the photodiode area and expose the source/drain area of each transistor.

Then, high-density n⁺ type dopants are implanted onto the exposed source/drain area using the patterned second photoresist film 69 as a mask, to form an n⁺ type diffusion area (floating diffusion area) 70.

After that, referring to FIG. 3D, the second photoresist film 69 is removed and a third photoresist film 71 is coated on the entire surface of the semiconductor substrate 61. An exposure and development process is performed relative to the third photoresist film 71, so that the third photoresist film 71 is patterned to expose each photodiode area.

Then, p⁰ type dopants are implanted onto the photodiode area having the n⁻ type diffision area 67 using the patterned third photoresist film 71 as a mask, thereby forming a p⁰ type diffusion area 72 on the surface of the semiconductor substrate.

Subsequently, referring to FIG. 3E, the third photoresist film 71 is removed and a heat-treatment process is performed with respect to the semiconductor substrate 61, to diffuse each impurity diffusion area.

In general, studies and research have been continuously performed to enhance the integration degree and to improve sensitivity of the CMOS image sensor.

### BRIEF SUMMARY

An object of the present invention is to provide a CMOS image sensor and a method for manufacturing the same, capable of improving sensitivity of the image sensor while maintaining an integration degree thereof. In a preferred embodiment, a CMOS image sensor and a method for manufacturing the same can be capable of improved sensitivity by increasing the unit area of a photodiode.

According to one aspect of the present invention, there is provided a CMOS image sensor comprising: a semiconductor substrate having an active area and an isolation area; a photodiode area and a transistor area defined on the active area; a plurality of semiconductor patterns formed on the photodiode area; a transistor formed on the transistor area; a first conductive type first diffusion region formed on the photodiode area; a first conductive type second diffusion region formed on the transistor area; and a second conductive type third diffusion region formed on the first diffusion area.

According to another aspect of the present invention, there is provided a method for fabricating a CMOS image sensor, the method comprising the steps of: forming an active area and an isolation area on a semiconductor substrate; forming a plurality of semiconductor patterns on a photodiode area of the active area; forming a gate insulating layer and a gate electrode on a transistor area of the active area; forming a first conductive type first diffusion region on the photodiode area; forming insulating layer sidewalls at both sides of the gate electrode; forming a first conductive type second diffusion region on the transistor area; and forming a second conductive type third diffusion region on the first diffusion area.

### BRIEF DESCRIPTION OF THE DRAWINGS

FIG. 1 is an equivalent circuit diagram illustrating a 4T-type CMOS image sensor according to a related art.

FIG. 2 is a layout view showing a unit pixel of a 4T-type CMOS image sensor according to the related art.

FIGS. 3A to 3E are sectional views taken along line I-I′ of FIG. 2 to illustrate a procedure for fabricating a CMOS image sensor according to the related art.

FIG. 4 is a sectional view showing a CMOS image sensor according to an embodiment of the present invention.

FIGS. 5A to 5F are sectional views illustrating a procedure for fabricating a CMOS image sensor according to an embodiment of the present invention.

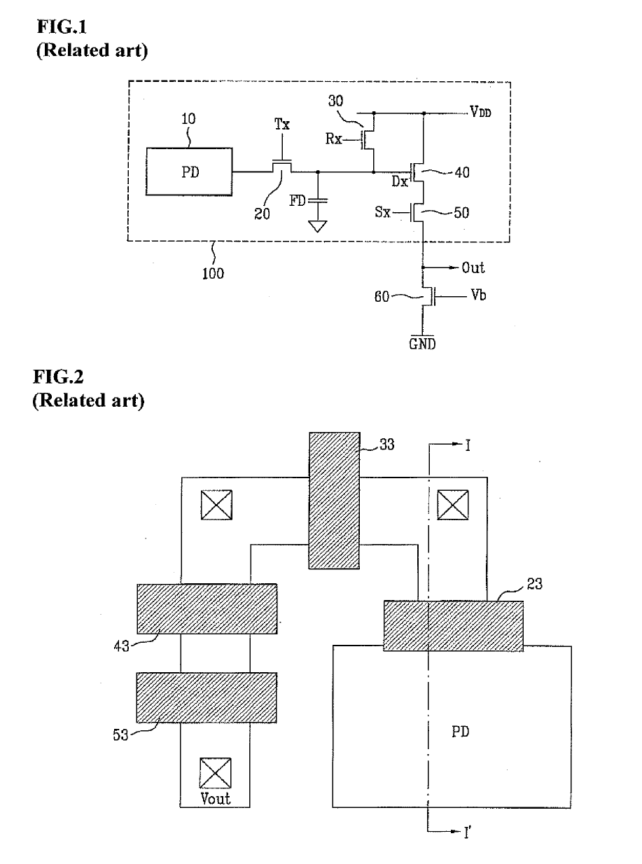

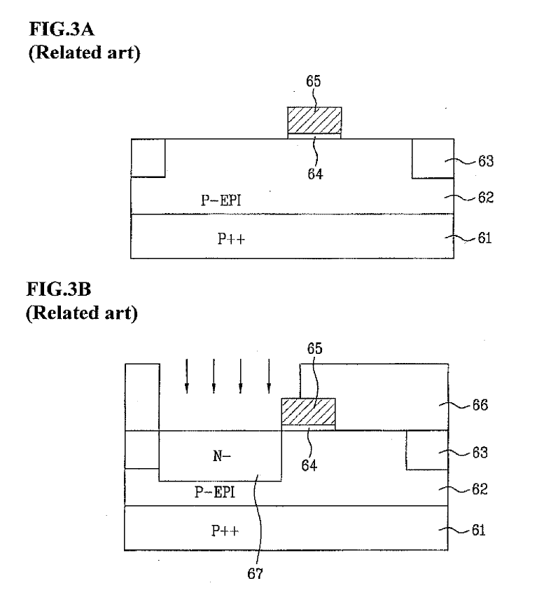

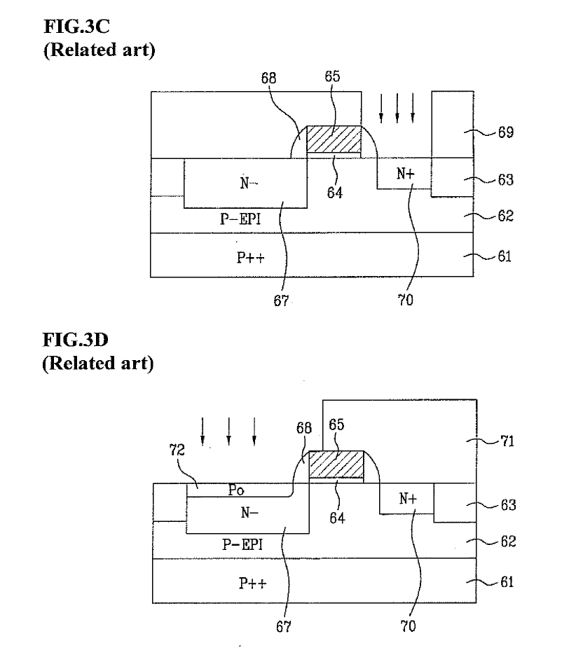

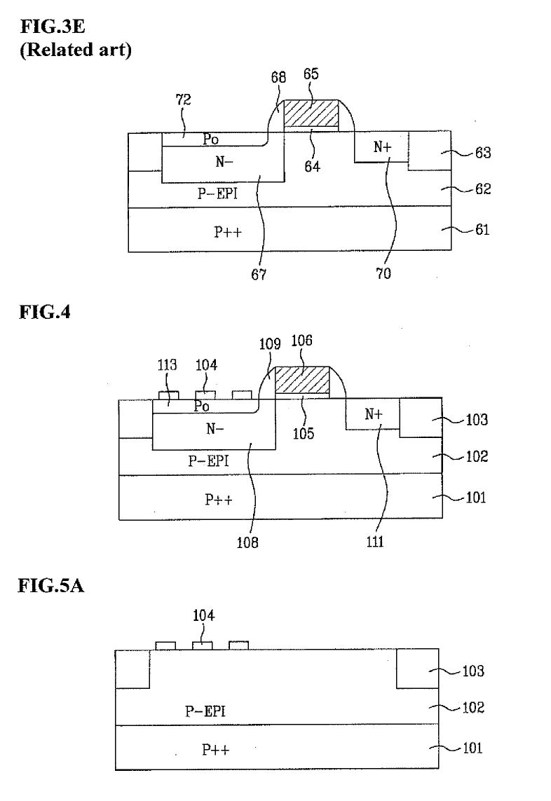

### DETAILED DESCRIPTION OF THE PREFERRED EMBODIMENTS

Hereinafter, a CMOS image sensor and a fabrication method thereof according to preferred embodiments of the present invention will be described with reference to the accompanying drawings.

FIG. 4 is a sectional view showing a CMOS image sensor according to an embodiment of the present invention.

As shown in FIG. 4, the CMOS image sensor can include a p⁻ type epitaxial layer 102 formed on a p++ type conductive semiconductor substrate 101, on which an active area including a photodiode area and a transistor area and an isolation area are defined. In addition, the CMOS image sensor can include an isolation layer 103 formed on the isolation area to define the active area of the semiconductor substrate 101; a plurality of semiconductor patterns 104 formed on the photodiode area of the semiconductor substrate 101; a gate electrode 106 formed on the active area of the semiconductor substrate 101 with a gate insulating layer 105 interposed therebetween; a low-density n⁻ type diffusion area 108 formed on the photodiode area of the semiconductor substrate 101; insulating layer sidewalls 109 formed at both sides of the gate electrode 105; a high-density n⁺ type diffusion area (floating diffusion area) 111 formed on the transistor area at a side of the gate electrode 105; and a P⁰ type diffusion area 113 formed on the semiconductor substrate 101 where the low-density n⁻ type diffusion area 108 is formed.

In a specific embodiment, the semiconductor pattern 104 can include a p type epitaxial layer. Since the surface area of the photodiode area can be enlarged due to the semiconductor patterns 104, the photo-sensitivity of the image sensor can be improved without increasing the surface area of the photodiode.

In a further embodiment, a high-density p⁺ type impurity area (not shown) can be formed in the vicinity of the isolation layer 103.

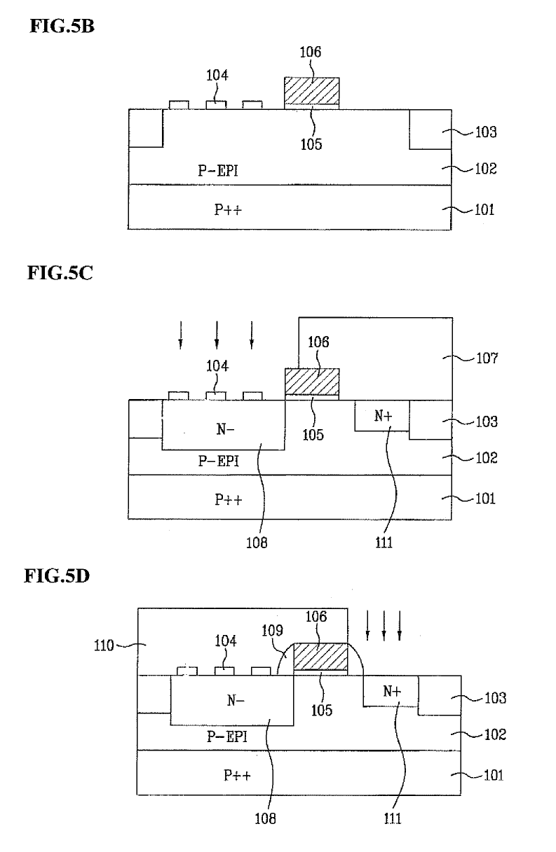

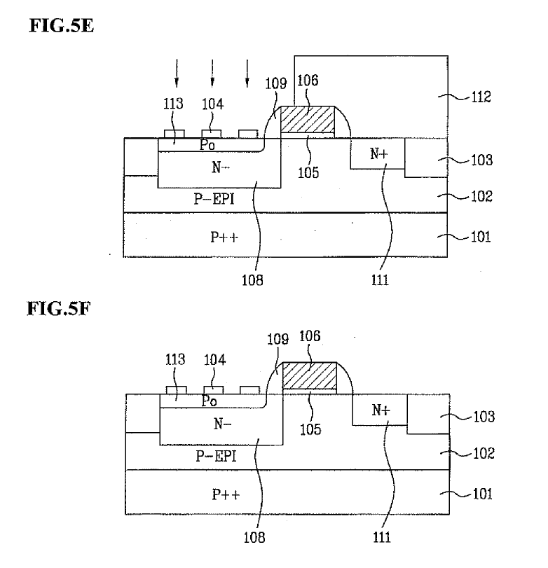

FIGS. 5A to 5F are sectional views illustrating a procedure for fabricating a CMOS image sensor according to an embodiment the present invention.

Referring to FIG. 5A, an epitaxial process can be performed with respect to a high-density p++ type semiconductor substrate 101, thereby forming a low-density P⁻ type epitaxial layer 102.

Then, after defining the active area and the isolation area on the semiconductor substrate 101, an isolation layer 103 can be formed on the isolation area through an STI (shallow trench isolation) process.

Although not shown in the figures, the process for forming the isolation layer 103 can be as follows:

First, a pad oxide layer, a pad nitride layer and a TEOS (tetra ethyl ortho silicate) oxide layer are sequentially formed on a semiconductor substrate. Then, a photoresist film is formed on the TEOS oxide layer.

After that, the photoresist film is subject to an exposure and development process using a mask that defines an active area and an isolation area, thereby patterning the photoresist film. At this time, the photoresist film formed on the isolation area is removed.

Then, the pad oxide layer, the pad nitride layer and the TEOS oxide layer on the isolation area are selectively removed by using the patterned photoresist film as a mask.

Next, the isolation area of the semiconductor substrate is etched to a predetermined depth using the patterned pad oxide layer, pad nitride layer and TEOS oxide layer as an etch mask, thereby forming a trench. After that, the photoresist film is completely removed.

Then, the trench is filled with an insulating material, thereby forming the isolation layer 103 in the trench. After that, the pad oxide layer, the pad nitride layer and the TEOS oxide layer are removed.

Referring again to FIG. 5A, a semiconductor layer (for example, a p type epitaxial layer) can be formed on the entire surface of the semiconductor substrate 101. Then, the semiconductor layer can be selectively removed by photo and etching processes to form a plurality of semiconductor patterns 104 on the substrate 101. In one embodiment, the semiconductor patterns 104 can have a constant interval therebetween.

The semiconductor patterns 104 are formed on a predetermined region of the semiconductor substrate 101 where the photodiode area will be formed later.

Then, referring to FIG. 5B, a gate insulating layer 105 and a conductive layer (for example, a high-density multi-crystalline silicon layer) can be sequentially deposited on the entire surface of the semiconductor substrate 101 having the semiconductor pattern 104.

In an embodiment, the gate insulating layer 105 can be formed through a thermal oxidation process or a chemical vapor deposition (CVD) process.

Then, the conductive layer and the gate insulating layer 105 can be selectively removed to form a gate electrode 106.

The gate electrode 106 illustrated in the figures is a gate electrode of the transfer transistor.

Referring to FIG. 5C, a first photoresist film 107 can be coated on the entire surface of the semiconductor substrate 101 including the gate electrode 105, and selectively patterned by an exposure and development process to expose each photodiode area.

Then low-density second conductive type (n⁻ type) dopants can be implanted onto the epitaxial layer 102 using the patterned first photoresist film 107 as a mask, thereby forming an n⁻ type diffusion area 108 in the photodiode area.

Then, referring to FIG. 5D, the first photoresist film 107 can be completely removed and an insulating layer can be deposited on the entire surface of the semiconductor substrate 101 including the gate electrode 106. Then, an etch-back process can be performed to form an insulating layer sidewall 109 at both sides of the gate electrode 106.

Next, after coating a second photoresist film 110 on the semiconductor substrate 101 including the gate electrode 106, an exposure and development process can be performed relative to the second photoresist film 110 to cover the photodiode areas and to expose the source/drain area (floating diffusion area) of each transistor.

Then, high-density second conductive type (n⁺ type) dopants can be implanted onto the exposed source/drain area by using the patterned second photoresist film 110 as a mask, to form an n⁺ type diffusion area (floating diffusion area) 111.

Referring to FIG. 5E, the second photoresist film 110 can be removed and a third photoresist film 112 can be coated on the entire surface of the semiconductor substrate 101. Then exposure and development processes can be performed relative to the third photoresist film 110, so that the third photoresist film 110 is patterned to expose each photodiode area.

Then, first conductive type (p⁰ type) dopants can be implanted onto the epitaxial layer 102 formed with the n⁻ type diffusion area 108 using the patterned third photoresist film 112 as a mask, to form a p⁰ type diffision area 113 on the surface of the epitaxial layer 102.

After that, referring FIG. 5F, the third photoresist film 112 can be removed and a heat-treatment process can be performed to diffuse each impurity diffusion area.

Although not shown in the figures, a plurality of interlayer dielectric layers can be formed on the resultant structure and a color filter layer and a microlens can be formed, to complete formation of the image sensor.

As described above, the CMOS image sensor and the fabrication method thereof according to the present invention can have the following advantage.

That is, because a plurality of semiconductor patterns are formed on the photodiode area of the semiconductor substrate, the unit area of the photodiode can be enlarged, so that the photo-sensitivity and the characteristics of the image sensor can be improved.

It will be apparent to those skilled in the art that various modifications and variations can be made in the present invention. Thus, it is intended that the present invention covers the modifications and variations of this invention provided they come within the scope of the appended claims and their equivalents.

It should be understood that the examples and embodiments described herein are for illustrative purposes only and that various modifications or changes in light thereof will be suggested to persons skilled in the art and are to be included within the spirit and purview of this application.

I claim:

1. A CMOS image sensor comprising:
a photodiode area and a transistor area defined on an active area of a semiconductor substrate;
a plurality of semiconductor patterns formed on the photodiode area;
a transistor formed on the transistor area;
a first diffision region of a first conductive type formed on the photodiode area;
a second diffusion region of the first conductive type formed on the transistor area; and
a s third diffusion region of a second conductive type formed on the first diffusion region.

2. The CMOS image sensor according to claim 1, wherein the plurality of semiconductor patterns have heights identical to each other.

3. The CMOS image sensor according to claim 1, wherein the plurality of semiconductor patterns are formed having a constant interval therebetween.

4. The CMOS image sensor according to claim 1, wherein the transistor comprises a transfer transistor.

5. The CMOS image sensor according to claim 1, wherein the transistor comprises a gate insulating layer, a gate electrode formed on the gate insulating layer, and insulating layer sidewalls formed at both sides of the gate electrode.

6. The CMOS image sensor according to claim 1, wherein the plurality of semiconductor patterns are formed of an epitaxial layer of the second conductive type.

7. A method for fabricating a CMOS image sensor, comprising:
forming a plurality of semiconductor patterns on a photodiode area of an active area of a semiconductor substrate;
forming a gate insulating layer and a gate electrode on a transistor area of the active area;
forming a first diffusion region of a first conductive type on the photodiode area;
forming insulating layer sidewalls at both sides of the gate electrode;
forming a second diffusion region of the first conductive type on the transistor area; and
forming a third diffusion region of a second conductive type on the first diffusion area.

8. The method according to claim 7, wherein the plurality of semiconductor patterns have heights identical to each other.

9. The method according to claim 7, wherein the plurality of semiconductor patterns are formed having a constant interval therebetween.

10. The method according to claim 7, wherein the plurality of semiconductor patterns comprise an epitaxial layer of the second conductive type.

11. The method according to claim 7, wherein forming the plurality of semiconductor patterns comprises forming an epitaxial layer on the photodiode area and selectively removing portions of the epitaxial layer by performing photolithography and etching processes.
